(19) United States
(12) Patent Application Publication
(10) Pub. No.: US 2011/0108083 A1
(43) Pub. Date: May 12, 2011

(54) SUPPORT FOR A SOLAR PANEL

(76) Inventors: Frans Gerrit Ravestein, Woudenberg (NL); Geerling Loois, Boxtell (NL); Verius Leo Antonius Theunissen, Duiven (NL)

(21) Appl. No.: 12/808,113

(22) PCT Filed: Oct. 24, 2008
(86) PCT No.: PCT/EP08/09028

§ 371 Date: Jan. 20, 2011

(30) Foreign Application Priority Data
Dec. 14, 2007 (NL) 2001092

(51) Int. Cl. H01L 31/042; H01L 31/02; E04D 13/18

(52) U.S. Cl. 136/244; 136/252; 52/173.3

(57) ABSTRACT

The invention relates to a support (1) for a solar panel (100), particularly for mounting a solar panel (100), having a bottom part which has a base (2) and assembly elements which are provided on an underside of the base (2) and which are intended for the purpose of assembly on an essentially flat foundation, particularly a roof, having a top, which is essentially opposite the underside and which supports the panel, with fastening means which hold the solar panel (100) obliquely with respect to the bottom part or a roof plane in a mounted state, and having a front with a surface which directs the wind (140) and which is oriented obliquely inwards towards the top from a front region of the bottom part in order to direct wind (140) towards the top in the direction of an upper edge of a solar panel (100) mounted on the support (1), wherein the surface directing the wind has an upwardly oriented tangent (W1-W3) which extends in a region around the junction between the front and the top of the support and in a direction crossways with respect to the upper edge (101) of a solar panel (100) mounted on the support through the upper edge of the solar panel or outside the solar panel.

### BACKGROUND OF THE INVENTION

The invention relates to a support for a solar panel, in particular a support for holding or mounting a solar panel e.g. on a roof, as well as to an assembly comprised of the support and a solar panel.

The Dutch patent document 1031317 shows a box-shaped support for a solar panel. The support has a high side and a low side which extend from a bottom part angled away from one another, and which are provided with fixtures at the top side with which the solar panel is held in an inclined position with respect to a flat roof. In the Northern hemisphere, the high side is principally directed to the North in order to orient the panel towards the sun. The box-shaped support is filled with ballast in order to hold it in place. That may be gravel already present on the roof, which originally lay at the position of the support. This amount of gravel sometimes proves insufficient, however, to hold the support in place with a North wind frontally incident onto the high side, which is why additional ballast must be brought into place. This additional ballast, however, regularly presents an undesirable additional loading for the roof.

### BRIEF SUMMARY OF THE INVENTION

The invention is based on the aim to make available a support for a solar panel which can be sufficiently securely positioned with a relatively low ballast, and one possibly already present loose on a flat roof. A further object of the invention is to provide a support for a solar panel which can resist blowing wind well.

This object is solved by a support according to claim 1 for mounting a solar panel. Preferred features of the invention are recited in the dependent claims. Further, the invention provides an assembly which is comprised of a solar panel and a support according to the invention. The solar panel is typically relatively flat and preferably has a rectangular form.

According to the invention, a support for a solar panel, in particular for mounting a solar panel is provided comprising:
a bottom part, which comprises a base and positioning elements provided on an underside of the base, which are intended for standing the support on an essentially flat ground surface, in particular a roof;
a panel-supporting upper side essentially opposite the underside having fastening means which are adapted for holding a solar panel inclined with respect to the bottom part or a roof plane in a mounted state; and
a front side having a wind-guiding surface which is oriented from a front region of the base inclined inwardly upwards in order to guide wind upwards in the direction of an upper edge of a solar panel mounted on the support;
wherein the wind-guiding surface has an upwardly directed tangent which, in a region at the transition from the front side to the top side of the support and in a direction transverse to the upper edge of a solar panel mounted on the support, extends through the upper edge of the solar panel or outside a circumference of the solar panel.

The wind-guiding surface can guide a wind that is frontally incident onto it in a direction angled upward, i.e. at a rearwardly directed angle of less than 90 degrees with respect to the bottom part or the roof plane upon which the support is placed. The wind can thereby be guided over the assembly while exerting a downwardly directed force on the wind-guiding surface and possibly an upwardly directed suction force on the solar panel. By virtue that the upwardly directed tangent extends through the upper edge of the solar panel or outside of the solar panel, the wind can thus only exert a low upwardly directed force on the upper edge, as a result of which rearward tipping or overturning in the wind direction, sliding with the wind, or lifting of the panel can be restrained.

In a second aspect according to the invention, or alternatively formulated, a support for mounting a solar panel is provided comprising:
a bottom part which comprises a base and positioning elements provided on an underside of the base, which are intended for positioning the support on an essentially flat surface, particularly on a roof;
a panel-supporting upper side essentially opposite the underside having fastening means which are adapted to hold a solar panel in a mounted state inclined with respect to the bottom part or a roof plane; and
a front side with a wind-guiding surface which is oriented angled inwardly upwards from a front region on the base in order to guide wind upwards in the direction of a top edge of a solar panel mounted on the support;
wherein, when viewed in projection transverse to the bottom part or the roof plane and in a direction transverse to the top edge of a solar panel mounted on the support, the wind-guiding surface extends in a region outside a periphery of the solar panel.

In a preferred form of the invention, the bottom part is comprised of a base plate which includes positioning elements for positioning on the essentially flat ground surface, particularly a roof. The positioning elements are located at least in part on an underside of the base plate. In a preferred form of the invention, these positioning elements include edges or bearing edges or other bearing elements of the bottom part with which the support rests on the ground or the roof. The wind-guiding surface preferably extends into an area in the vicinity of the positioning elements beyond the circumference of the solar panel.

As mentioned above, the wind-guiding surface can direct wind frontally incident thereon in the direction obliquely upwards, i.e. at a rearward directed angle of less than 90 degrees with respect to the roof plane, wherein the wind can be guided over the assembly while exerting a downwardly directed force on the wind-guiding surface and possibly an upwardly directed suction force on the solar panel. By virtue of the wind-guiding surface extending into a region beyond the solar panel in projection transverse to the roof plane and in a direction transverse to the top edge of the solar panel, the downwardly directed force can exert a downwardly directed turning moment on the assembly that is larger than the upwardly directed turning moment that the suction force may exert to allow the assembly to overturn backwards in the wind direction. With one or more the aforementioned measures, the assembly remains for the most part standing stably of its own accord on the roof so that merely a small amount of ballast needs to be placed on the support.

In a preferred embodiment of the invention, a portion of the positioning elements is located beyond the solar panel at the opposite side of the support with respect to the wind-guiding surface, when viewed in a projection transverse to the ground surface and in a direction transverse to the upper edge of the solar panel. This portion of the positioning elements located beyond the solar panel determines a tipping region or tipping point of the support, which is located relatively far away from the wind-guiding surface. A reward overturning of the assembly as a result of frontally incident wind can thereby be counteracted.

In a preferred form of the invention, the wind can be guided over a substantial portion of the top edge of the solar panel when the wind-guiding surface extends over at least half of the width of the base part, further preferred at least ¾ of the width of the base part, viewed in a direction parallel to the upper edge.

In a preferred form of the invention, the dimensioning of the wind-guiding surface taken in a direction parallel to the upper edge decreases in an upwards direction. Formulated differently, the wind-guiding surface possesses a lateral boundary at both sides which is oriented inclined inwardly upwards from a side edge region of the bottom part. These lateral boundaries are particularly advantageous when multiple supports are positioned next to one another. The decreasing width or the inclination of the lateral boundaries results in openings or gaps being formed between the wind-guiding surfaces through which a portion of the incident wind can pass under the solar panels for pressure equalization with respect to the wind guided over the solar panels. The wind thereby has a limited grasp on the assembly and the solar panels can be cooled by the wind.

In a simple embodiment of the invention, the wind-guiding surface is substantially straight in the upwards direction.

In an aerodynamically favourable embodiment of the invention, the wind-guiding surface is substantially smooth.

In a preferred embodiment of the invention, the solar panel stands at an angle of 10 to 40 degrees with respect to the roof plane. Preferably, the solar panel stands at an angle from 10 to 20 degrees with respect to the roof plane. This angle is admittedly not optimal for an individual solar panel in Northern Europe but multiple assemblies can then be positioned so close to one another in the direction transverse to the top edge that the efficiency factor for a fully covered roof is very satisfactory.

Upwardly directed suction forces on the panel with the aforementioned angle can be satisfactorily compensated by the wind-guiding surface when the wind-guiding surface comprises an upwardly oriented tangent having an angle from 40 to 80 degrees, preferably from 40 to 70 degrees, and further preferably 50 to 60 degrees, with respect to the roof plane.

In a development of the invention, the fastening means comprise first, preferably distributedly positioned, fastening parts which engage the upper edge of the solar panel.

The obliquely upwardly guided wind experiences only a limited obstruction through the presence of the first fastening parts if the first fastening parts form a continuation of at least a portion of the wind-guiding surface. The first fastening parts preferably form a direct continuation of at least a portion of the wind-guiding surface. The first fastening parts may actively contribute to the guiding of the wind over the top edge when the first fastening parts extend over the top edge of the solar panel.

In a preferred form of the invention, the first fastening parts are provided with a first overlap section that reaches over the top edge, wherein the overlap section defines a first groove under its lower side in which the top edge is received. The solar panel can then be mounted on the support by the top edge being enclosed in the groove.

In a further development, the fastening means comprise second, preferably distributedly positioned, fastening parts which engage a lower edge of the solar panel extending opposite the top edge. The solar panel can thereby be fastened on the support at two opposite sides.

In a preferred embodiment of the invention, the second fastening parts extend over the lower edge of the solar panel, wherein the second fastening means are preferably provided with a second overlap section that reaches over the lower edge, wherein the overlap section defines a second groove at its lower side in which the lower edge is received.

The notching effect in the limit of the second groove resulting from the self-weight of the panel can be counteracted when the second fastening means, other than the overlap section, comprises an abutment surface which lies against the lower edge to hold this away from the bottom limit of the groove.

In a preferred form of the invention, the support or the assembly of support and solar panel can be weighted with ballast and thereby stabilized when the support comprises at least one ballast chamber, e.g. accessible from the upper side. The ballast chamber may hold loosely poured ballast, such as gravel already present on the roof, inside it in its place.

The introduction of ballast into the ballast chamber creates a favourable low centre-of-mass for the assembly. In an embodiment of the invention, the ballast chamber includes a floor which forms a portion of the bottom part of the support.

In a preferred embodiment, the ballast chamber is located centrally with respect to the positioning elements or the edges of the bottom part. Alternatively, or in addition, the support includes a ballast chamber at a short spacing from a lateral edge of the bottom part extending transverse to the front side.

In a preferred form of the invention, lateral boundaries of the wind-guiding surface form openings or spaces through which a portion of the incident wind can enter below a solar panel mounted on the support.

In a preferred embodiment of the invention, the support comprises a first elevation or a first ridge at the front side, a front wall of which forms or includes the wind-guiding surface. This elevation or this ridge can contribute to a stiffening of the support so that the frontal wind is incident upon a relatively stiff portion of the support.

In a preferred embodiment of the invention, the first elevation or the first ridge extends parallel to the upper edge of the solar panel. The first elevation or the first ridge can thereby endow a thin-walled embodiment of the support additional stiffness, e.g. in the direction of the upper edge.

For the further stiffening of the support, this elevation or this ridge may be provided at its front side with indentations and/or protrusions. A facing surface of the elevation or the ridge can thereby form a stiffened wind-guiding surface. Preferably, the indentations and/or protrusions in this facing surface extend substantially parallel to one another and preferably with an upward orientation.

In a preferred embodiment, the first elevation or the first ridge is arranged with at least a portion of the fastening means at its upper side.

In a preferred embodiment of the invention, the support comprises a second elevation or a second ridge. Preferably, the second elevation or the second ridge extends substantially parallel to the top edge of the solar panel and can thereby endow a thin-walled embodiment of the support additional stiffness in the direction transverse to the top edge. The second elevation or the second ridge preferably has an upper side which continues obliquely downwards towards the bottom part.

In a thin-walled or light-weight embodiment of the support, the first and/or second elevation or the first and/or second ridge is essentially hollow. In a preferred embodiment of the invention, the first and second elevation or the first and second stiffening ridge are connected with one another via one or more elongate ribs or reinforcing ribs. The second ridge preferably merges into the first ridge, whereby the ridges may form a stiffening cross-joint.

The aforementioned ballast chamber may be bounded by sufficiently stable walls if the first and second elevation or the first and second ridge bound at least a portion of the ballast chamber.

Multiple supports can be coupled together with one another in the direction of the upper edge to form a complete support for multiple solar panels when the support comprises a first and second side margin extending transverse to the front side that is equipped with a first or second hollow coupling elevation, wherein the first coupling elevation is constructed to at least partially receive the second coupling elevation of an identical support via nesting in one another.

In a light-weight and thereby easily transported and manipulated embodiment of the invention, the support as a whole, and preferably entirely, is manufactured from a thin-walled material, preferably polyethylene, preferably by means of vacuum forming.

In a preferred form of the invention, the support is formed so that it can be stacked on an identical support via nesting in one another. Multiple supports can be transported compactly stacked when the support is formed to be stacked on a same or identical support via a nesting in one another.

### BRIEF DESCRIPTION OF THE DRAWINGS

The invention will now be explained with reference to particular embodiments illustrated in the accompanying drawings. They show:

FIG. 1A an isometric rear view of a support according to an embodiment of the invention, without solar panel;

FIG. 1B an isometric rear view of a support according to an embodiment of the invention, with solar panel;

FIG. 1C two supports according FIGS. 1A and 1B in their mutual extension coupled to one another on a flat roof;

FIG. 2A an isometric front view of the support shown in FIG. 1A;

FIG. 2B an isometric front view of the support shown in FIG. 1B;

FIG. 3A side views of the support shown in FIG. 1A;

FIG. 3B side views of the support shown in FIG. 1B.

### DESCRIPTION OF THE EMBODIMENTS OF THE INVENTION

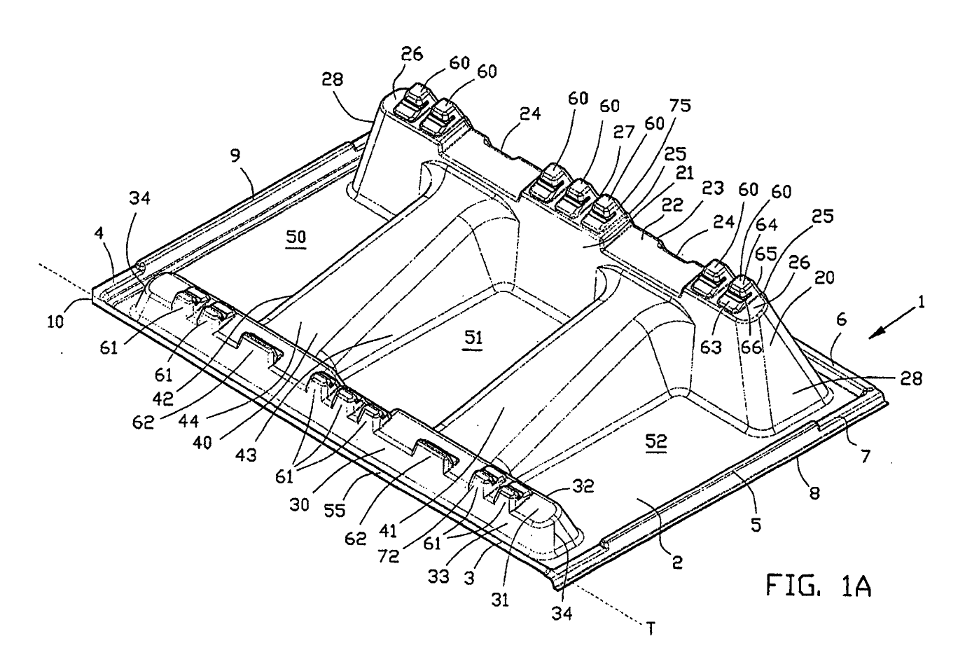

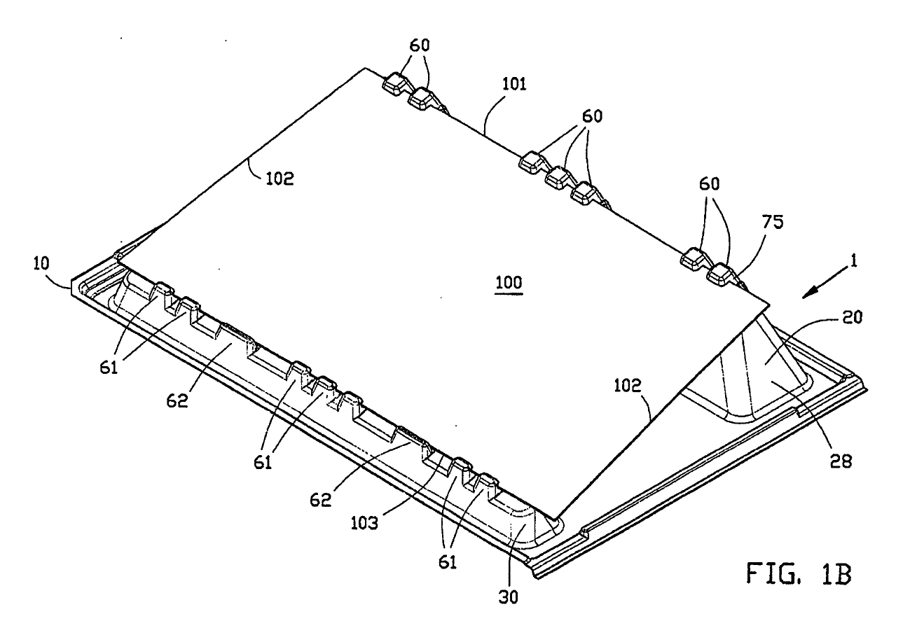

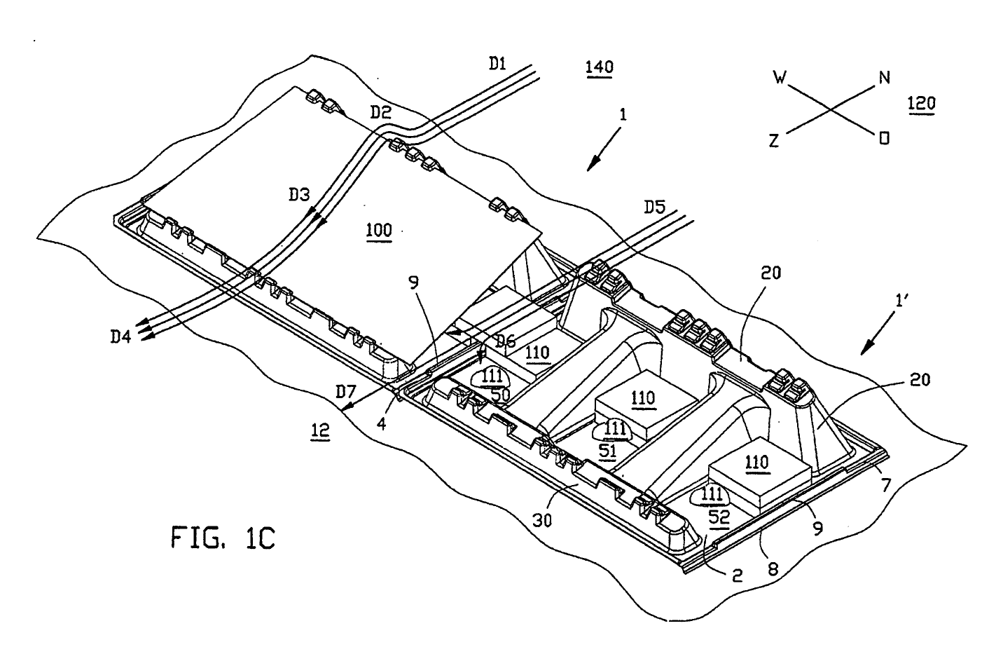

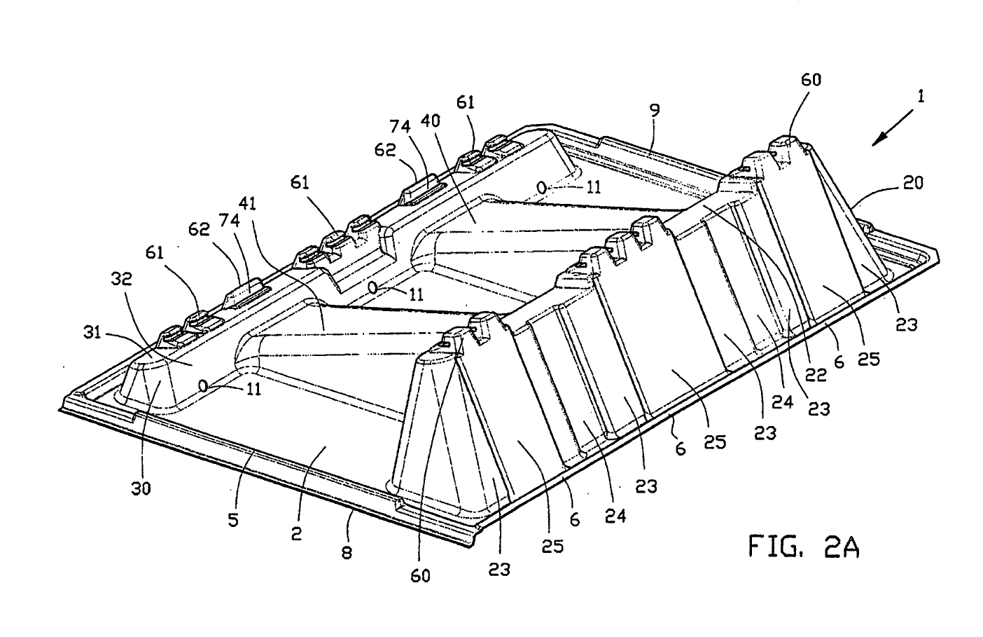

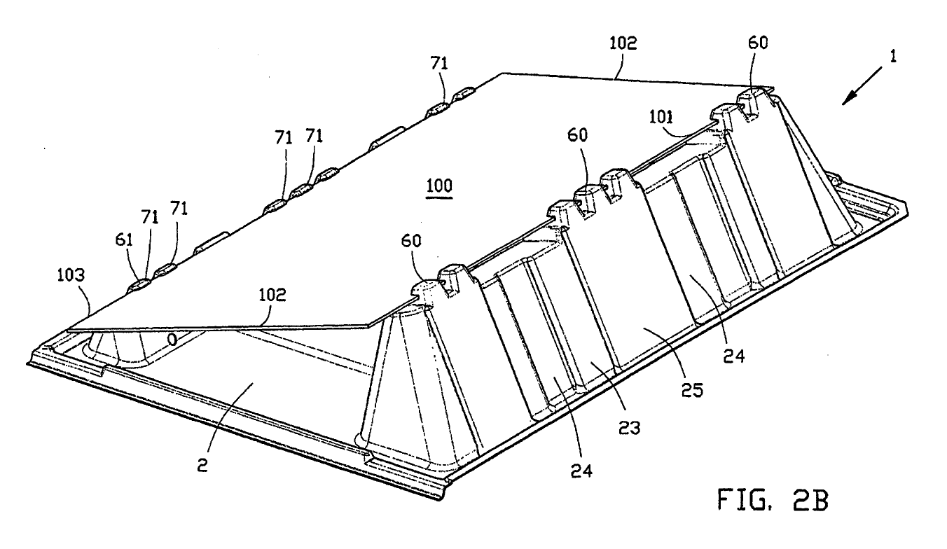

The FIGS. 1A, 2A and 3A show a support 1 for a solar panel 100 according to an embodiment of the invention. In the FIGS. 1B, 2B and 3B, a solar panel 100 is attached on the support 1, in FIG. 1C two identical supports 1, 1′ are coupled to one another and installed using ballast 110, 111 on a flat roof 12. In the Northern hemisphere, for example in Europe, the solar panel 100 is oriented to the South, corresponding to the illustrated compass.

The thin-walled support 1 is molded as a whole or entirely commencing from a flat plastic plate, for example of polyethylene, e.g. by means of vacuum forming. The support 1 is provided with a bottom part, which is essentially comprised of a flat base 2, within the peripheral limits of which a large elevation 20 in the form of a high ridge at the front side and a small elevation 30 in the form of a low ridge at the rear side protrude out of the base 2. The high and low elevations and ridges 20, 30 extend substantially parallel to a front and a rear edge of the support 1 and thereby serve as a stiffening for the support. Additionally, these high and low elevations or ridges 20, 30 are connected with one another by means of two downwardly extending elongate ribs or further stiffening ridges 40, 41. The ridges or ribs 20, 30, 40, 41 are hollow inside and merge smoothly into one another. The support 1 is also formed such that it is self-releasing from its vacuum molding tool.

The high ridge 20 comprises an inclined facing surface or front wall 23 having parallel indentations 24 and protrusions 25 for stiffening the front wall 23. The front wall 23 merges over a flat upper surface 22 into an opposite inclined inner wall 21 of the high ridge 20. The high ridge 20 is bounded at its ends by inclined side walls 28, whose inclination with respect to the roof 12 is substantially the same as the inclination of the front wall 23.

In the extension of the protrusions 25 in the front wall 23, a central rise 27 and two lateral rises 26 are formed on the upper surface 22, in which upper insert connectors 60 to be described in more detail are formed. The upper insert connectors 60 are distributed over the rises 26, 27; and indeed, there are two on the lateral rises 26 and three on the central rise 27.

The low ridge 30 comprises a rear wall 33 inclined with respect to the base 2 which merges by means of a flat upper surface 33 into an opposite inclined inner wall 32 having water drainage openings 11. The ends of the low ridge 30 are bounded by inclined side walls 34, whose inclination with respect to the roof 12 is substantially the same as the inclination of the front wall 23. On the upper surface 31 are formed lower insert connectors 61 to be described in more detail and hollow bearing parts 62 located between them. The bearing parts 62 are provided with abutment surfaces 74. The lower insert connectors 61 stand precisely opposite to the upper insert connectors 60. The high ridge 20 and the low ridge 30 extend over at least ¾ of the width of the base or the base plate 2.

The two elongate ribs or ridges 40, 41 have a flat upper surface 44 which merges into inclined side walls 42, 43 at the sides. The side walls 42, 43 facing one another in the two elongate ridges 40, 41 define, together with the base 2, a centrally located recessed ballast chamber 51, whereas the outer sidewalls 42, 43 together with the base 2 define two outer ballast chambers 50, 52.

As illustrated in FIGS. 1B, 2B and 3B, a solar panel or photovoltaic panel PV-panel 100 is mounted on the support 1. The solar panel 100 has a rectangular contour with an upper edge 101, a lower edge 103 and two shorter side edges 102. The basis of the solar panel is a glass plate which can be manufactured with a compact metal rail along the edges 101, 102, 103 in order to avoid cut wounds in the handling of the solar panel 100. The upper edge 101 and the lower edge 103 plugs into the upper insert connectors 60 and lower insert connectors 61, respectively, whereby the lower edge 103 rests against the bearing parts 62.

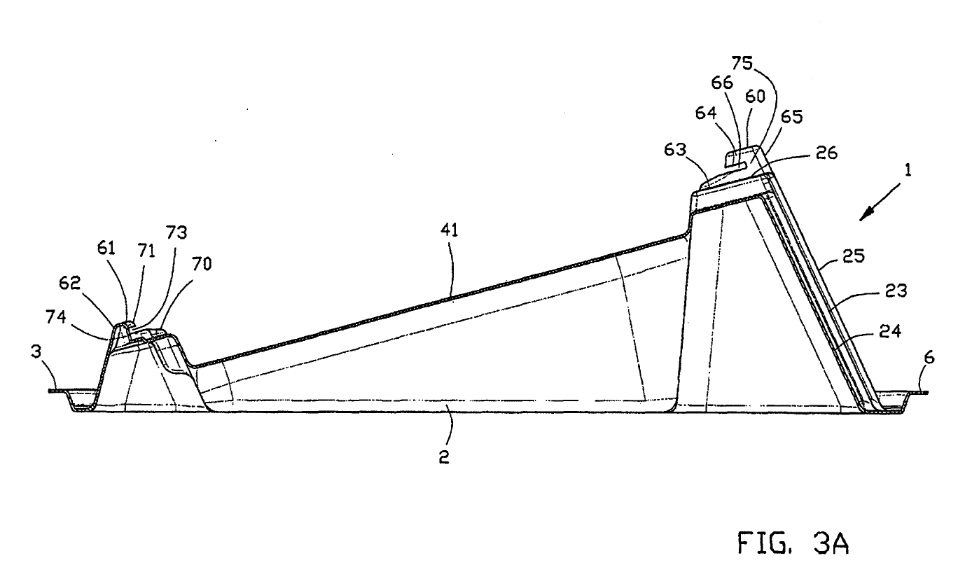

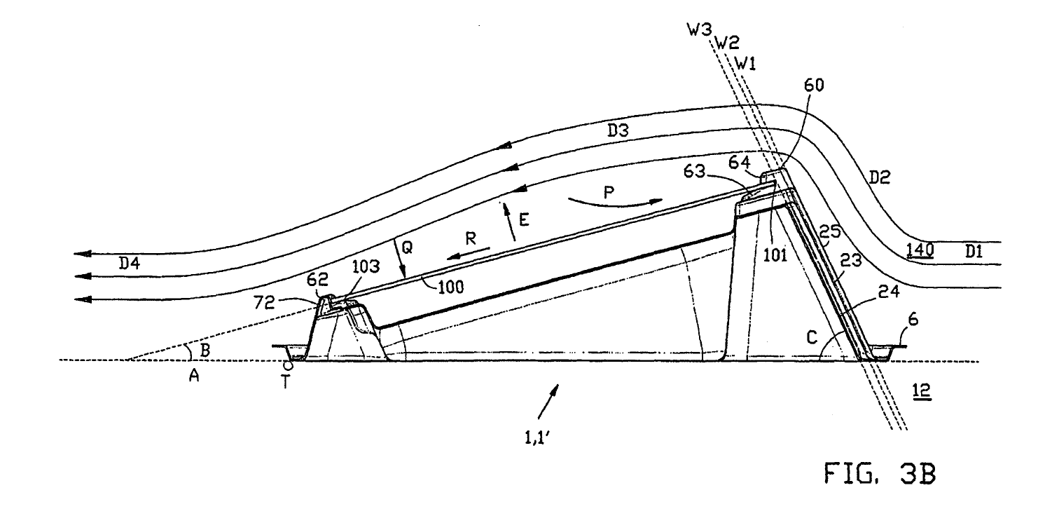

The front wall 23 in this example is directly oriented to the North although a slight inclination to the Northwest or the Northeast is also possible. The high ridge 20 and the low ridge 30 provide for an inclination of the solar panel 100 with respect to the base 2 towards the South at an angle B, in this example, of about 15 degrees with respect to the horizontal plane A of the roof 12, as shown in FIG. 3B. This inclination allows for a good collection of sunlight on the solar panel 100 as well as drainage of rainwater that falls onto the solar panel 100. The upper surfaces 22, 31, 44 of the ridges 20, 30, 40, 41 lie at the same angle parallel to the solar panel 100. The front wall 23 having the plane or tangent W2, the protrusions 25 having the upper plane or tangent W1 and the indentations 24 having the lower plane or tangent W3 extend parallel to one another at an angle C of approximately 65 degrees with reference to the plane A of the flat roof 12.

Each of the upper insert connectors 60 is hollow inside and includes a first lead-in surface 63 oriented at an angle to the plane of the solar panel 100 and a first overlap section 64 having a front wall 65 and a first transversely extending slot or groove 66, wherein the first lead-in surface 63 merges on the upper side into the bottom limit of the first transversely extending groove 66, and the front wall 65 lies in the same plane W1 as the protrusions 25 in the front wall 23 of the high ridge 20.

In a similar manner, each of the lower insert connectors 61 is hollow on the inside and includes a second lead-in surface 70 oriented at an angle to the plane of the solar panel 100 and a second overlap section 71 having a rear wall 72 and a second transversely extending slot or groove 73, wherein the second lead-in surface 70 merges on the lower side into the bottom limit of the second transversely extending groove 73. The first and second grooves 66, 73 have a rounded bottom limit, in order to counteract stress concentrations or tearing in the thin wall material as a result of upwardly directed forces at the free end of the overlap sections 64, 71.

The upper insert connectors 60 are stronger and more robustly formed than the lower insert connectors 61 as the footprint 65 of the upper insert connectors 60 in the extension of the transverse groove 66 is broader than for the lower insert connectors 61.

In the direction of the plane of the solar panel 100, the second groove 73 is somewhat deeper than the abutment surface 64 of the bearing parts 62 directed to the lower edge 103. The second transversely extending groove 73 is, however, less deep than the first transversely extending groove 66. The distance between the junction of the first lead-in surface 63 and the first groove 66, on the one hand, and the opposite junction of the second lead-in surface 70 and the second groove 73, on the other hand, is such that the top edge 101 of the solar panel 100 can be inserted into the first groove 66 in the direction P sufficiently deeply to bring the lower edge 103 in front of the second groove 73 in the direction Q lying on the second lead-in surface 70. Subsequently, the lower surface 103 can be inserted into the second groove 73 in the direction R. The lower edge thereby comes to rest against the bearing parts 62 and the top edge 101 remains sufficiently deeply in the first groove 66 as to remain enclosed therein. The rounded bottom limit of the second groove 73 remains out of contact with the lower edge 103 so that the rounding retains its useful form.

Alternatively, the solar panel 100 may be accommodated with the upper edge 101 and the lower edge 103 fitting in the grooves 66, 73 in such a manner that the solar panel 100 can only be introduced into the connectors 60, 61 via a sideways insertion.

In the periphery of the bottom part the support 1 is formed having, upstanding from the base plate 2, a front stiffening edge 6, a right lateral stiffening edge 7, a rear stiffening edge 3 and a left lateral stiffening edge 4. The right stiffening edge 7 is continued downwards to a supporting edge 8, which in turn is provided on an underside of the base 2. A first centrally positioned hollow coupling rise 5 is formed on the upper side. The left stiffening edge 4 is likewise continued downwards to another, non-illustrated supporting edge on the underside of the base 2, and on the upper side a second coupling rise 9 is formed whose internal side is large enough to fittingly receive the first coupling rise 5. The underside of the base wall 2 together with the supporting edges 8 form positioning elements with which the support 1 rests upon the roof 12. The corner of the left stiffening edge 4 is provided with a chamfer 10 so that the supports 1, 1′ can be coupled with one another, as illustrated in FIG. 1C.

The inclination of the parts of the support 1 which protrude upwardly from the base 2 is specified so that the support 1 is self-releasing from the moulding tool after vacuum forming. Thereafter, only the grooves 66, 73 of the insert connectors 60, 61 need to be formed. With this shape, the supports 1, 1′ are nestable in one another in the vertical direction such that a compact stack is achieved which is simple to transport. This nestable form of the support is particularly important because a relatively large number of supports and solar panels are typically installed on a single roof, e.g. in rows arranged directly next to one another which completely cover a large part of the roof surface.

As illustrated in FIG. 1C, after coupling the supports to one another, two paving stones 110 are placed on one another in the central ballast chamber 51. In the outer ballast chambers 51, 52, a paving stone 110 is placed with a further paving stone 110 on top of it extending over the coupled coupling rises 5, 9 in order to maintain this connection. The base dimensions of the ballast chamber 50, 51, 52 are such that standard paving stones of 30×30 cm can be employed. Instead of or supplemental to the paving stones, portions of gravel 111 may be used which, for example, already lay on the flat roof at the position of the supports 1, 1′.

FIG. 3B shows the support 1 with solar panel 100 under the influence of a wind 140 frontally incident in the direction D1. The wind 140 is guided over the surface of the inclined front wall 23 in the direction D2 so that the front wall 23 including the protrusions 25 and the indentations 24 absorbs a downwardly directed force from the wind onto the support 1. The wind subsequently deflects to move in the direction D3 over the solar panel 100 and in the horizontal direction D4 further over the roof 12. Considering that the upper edge 101 of the solar panel 100 is further set back compared to the planes or tangents W1-W3 of the surface of the front wall 23, the frontal wind 140 only exerts a low force on the upper edge 101 because the wind 140 has little access to it. Although the solar panel 100 may experience an upwardly directed suction force E from the wind 140, the ballast 110 and the far back or rearwardly positioned tipping point T in the tipping region of the support counteract this so that the assembly does not overturn rearwardly in the wind direction. Viewed from above and perpendicular to the plane A of the roof 12, the tipping region about the tipping point T lies beyond the lower edge 103 of the solar panel 100.

A portion of the wind 140 which arrives in a direction D5 between the side walls 28 of the successively following high ridges 20 partially enters in the direction D6 under the solar panels 100 and moves further in direction D7 to leave the subspace. Through this ventilation, the solar panels are cooled on the one hand, and an air pressure equalization with respect to the solar panels 100 occurs on the other hand, whereby the wind 140 has less hold on the assembly of the supports 1, 1′ with the solar panels 100. The assembly, at least at the front side and the upper side, thus has the shape of a spoiler with favourable aerodynamic properties with regard to the wind 140.

In the previously explained embodiment, the solar panel 100 is at the said angle B of about 15 degrees with respect to the plane A of the roof 12. In Northern and Central Europe this angle is not optimal for the individual solar panel, but with the resulting low height of the top edge 101, the shadow effect on directly adjacent positioned supports with solar panels is so low that the yield from a fully occupied roof 12 is indeed optimal. For individual solar panels 100 or for a single row as coupled according to FIG. 1C, an angle of about 36 degrees is optimal for Northern and Central Europe.

The purpose of the previous description is to illustrate the operation of preferred examples of the invention and not to limit the scope of the invention. Based on the previous explanation, many variations will be clear to a skilled practitioner which are encompassed by the disclosure of the present invention.

1. A support for mounting a solar panel, comprising:
a bottom part which comprises a base and positioning elements provided on an underside of the base which are intended for placement on an essentially flat ground surface, in particular on a roof;
a panel-bearing upper side essentially opposite the underside having fastening means which hold the solar panel in a mounted state inclined with respect to the bottom part or a roof plane; and
a front side having a wind-guiding surface, which is directed from a front region of the bottom part inclined inwardly upwards, in order to guide wind in the direction of an upper edge of a solar panel mounted on the support;
wherein, in a region of the transition from the front side to the upper side of the support and in a direction transverse to the upper edge of a solar panel mounted on the support, the wind-guiding surface has an upwardly directed tangent which extends through the upper edge of the solar panel or outside of the solar panel.

2. (canceled)

3. A support according to claim 1, wherein lateral boundaries of the wind-guiding surface form openings or spaces through which a portion of the incident wind can enter under a solar panel mounted on the support.

4. A support according to claim 1, wherein the support includes a first elevation at the front side, a front wall of which forms the wind-guiding surface.

5. A support according to claim 4, wherein the support includes a second elevation at the rear side, wherein the first and the second elevation determine the inclined orientation of the solar panel with respect to the base or the roof plane.

6. A support according to claim 5, wherein the first and the second elevation respectively have an upper surface, wherein the upper surfaces form the panel-bearing upper side of the support and thereby define the inclined orientation of the solar panel with respect to the base or the roof plane.

7. A support according to claim 6, wherein the fastening means for fastening the solar panel are located at the upper surfaces of the first and second elevations.

8. A support according to claim 5, wherein side walls of the first elevation form lateral boundaries of the wind-guiding surface, whereby the wind can pass the side walls and enter into a sub-space between the solar panel and the bottom part of the support.

9. A support according to claim 8, wherein side walls of the second elevation or the second ridge are formed in such a manner that the wind moving through the sub-space between the solar panel and the bottom part can move past the side walls and out of the sub-space.

10. A support according to claim 5, wherein the first elevation and the second elevation are connected with one another by means of at least one stiffening rib or elongate ridge.

11. (canceled)

12. A support according to claim 1, wherein the wind-guiding surface extends in a direction parallel to the upper edge over at least half of the width of the bottom part.

13. A support according to claim 1, wherein the width of the wind-guiding surface in a direction parallel to the upper edge decreases in the upwards direction, with lateral boundaries at opposite sides of the wind-guiding surface being angled inwardly upwards from a lateral edge region of the bottom part.

14. (canceled)

15. A support according to claim 1, wherein the wind-guiding surface is substantially straight and substantially flat.

16. A support according to claim 1, wherein the upper side of the support is constructed in such a manner that the solar panel is supported at an angle from 10 to 40 degrees with respect to the underside or a roof plane.

17. A support according to claim 1, wherein the wind-guiding surface comprises an upwardly directed tangent which is at an angle from 40 to 70 degrees with respect to the underside or a roof plane.

18. A support according to claim 1, wherein fastening means comprise first, fastening parts which engage the upper edge of the solar panel, wherein the first fastening parts are provided with a first overlap section which extends or reaches over the upper edge of the solar panel, the overlap section defining a first groove at its underside within which the upper edge of the solar panel is received.

19. A support according to claim 18, wherein the first fastening parts form a direct continuation of at least a portion of the wind-guiding surface.

20. (canceled)

21. A support according to claim 18, wherein the first fastening parts are provided with a first overlap section which extends or reaches over the upper edge of the solar panel, wherein the overlap section defines a first groove at its underside within which the upper edge of the solar panel is received.

22. A support according to claim 18, wherein the fastening means comprise second fastening parts which engage a lower edge of the solar panel extending opposite the upper edge, wherein the second fastening parts comprise a second overlap section that reaches over the lower edge, the second overlap section defining a groove at its underside in which the lower edge of the solar panel is received.

23. (canceled)

24. (canceled)

25. (canceled)

26. A support according to claim 1, wherein the support comprises at least one ballast chamber accessible from the upper side, wherein the ballast chamber has a base that forms at least a portion of the bottom part.

27. (canceled)

28. A support according to claim 26, wherein the ballast chamber is located centrally with respect to the positioning elements.

29. A support according to claim 26, wherein the ballast chamber is located at a short spacing from a side edge of the bottom part of the support extending transverse to the front side.

30. (canceled)

31. (canceled)

32. A support according to claim 5, wherein the support comprises at least one ballast chamber accessible from the upper side, and wherein the first and second elevation define at least a portion of the ballast chamber.

33. A support according to claim 1, wherein the support includes first and a second side edge region extending transverse to the front side, each provided with a first or second hollow coupling member, wherein the first coupling member is constructed to at least partially receive the second coupling member of an identical support.

34. A support according to claim 1, wherein the support is formed so as to be stacked on an identical support by nesting in one another.

35. A support according to claim 34, wherein the support is molded substantially entirely from thin-walled plastic material.

36. (canceled)

37. An assembly comprising:
at least one support according to claim 1; and
a solar panel mounted on the support.

38. An assembly according to claim 37, comprising multiple supports and multiple solar panels, wherein each of the solar panels is mounted on a respective one of the supports.

39. A support according to claim 4, wherein the first elevation is formed as an elongate ridge-like protrusion from the base that extends substantially parallel to the upper edge of the solar panel.

40. A support according to claim 5, wherein the first elevation is formed as an elongate ridge-like protrusion from the base and the second elevation is formed as elongate ridge-like protrusion from the base, wherein both of the first and second elevations extend substantially parallel to the upper edge of the solar panel.
